(19) United States
(12) Patent Application Publication
(10) Pub. No.: US 2010/0105157 A1
(43) Pub. Date: Apr. 29, 2010

(54) PROCESS OF MICRO-DISPLAY

(75) Inventors: Cheng-Hsun Lee, Taipei County (TW); Yi-Tyng Wu, Chiayi City (TW); Wei-Chen Sun, Hsinchu City (TW); Yuan-Sheng Chiang, Hsinchu City (TW)

Correspondence Address: NORTH AMERICA INTELLECTUAL PROPERTY CORPORATION, P.O. BOX 506, MERRIFIELD, VA, 22116, US

(73) Assignee: UNITED MICROELECTRONICS CORP., Hsinchu (TW)

(21) Appl. No.: 12/259,037

(22) Filed: Oct. 27, 2008

(51) Int. Cl. H01L 21/302

(52) U.S. Cl. 438/29; 257/E21.214

(57) ABSTRACT

A process of a micro-display is provided. First, a substrate having a pixel region and a periphery circuit region is provided, in which a metal reflection layer is formed in the pixel region, and a periphery circuit is formed in the periphery circuit region. Next, a dielectric layer is formed on the substrate to cover the pixel region and the periphery circuit region. Then, a patterned mask layer exposing the dielectric layer on the metal reflection layer is formed on the dielectric layer. Thereafter, a portion of the exposed dielectric layer is removed by using the patterned mask layer as a mask. Next, the patterned mask layer is removed. And then, a portion of the dielectric layer is removed to expose the metal reflection layer.

### BACKGROUND OF THE INVENTION

1. Field of the Invention

The present invention generally relates to a process of a micro-display, in particular, to process of a micro-display capable of preventing damage of a mirror layer and oxidation of a periphery circuit.

2. Description of Related Art

In recent years, liquid crystal pixel structures have been widely used in daily life gradually, for example, in liquid crystal screens of liquid crystal TVs, portable computers, or desktop computers, and in liquid crystal projectors. Micro-displays are applicable to various types of displays, for example, liquid crystal displays (LCD) or organic light-emitting diode (OLED) displays.

Generally speaking, in micro-display products, aluminum (Al) is always used as a material of a mirror layer to ensure good reflectivity of the mirror layer. In a process of a micro-display, in order to expose the mirror layer, blanket etching or chemical mechanical polishing (CMP) is used to remove the dielectric layer on the mirror layer in the prior art. However, when removing the dielectric layer on the mirror layer through the blanket etching or CMP, the dielectric layer on the periphery circuit will be inevitably removed together, thus exposing the periphery circuit, and resulting in the problem of the oxidation of the periphery circuit, which seriously impacts the performance of the device.

In order to solve the problem of the oxidation caused by the periphery circuit exposed in the blanket etching or CMP, a lithography process and an etching process are adopted to remove the dielectric layer on the mirror layer. However, after removing the dielectric layer on the mirror layer, the mirror layer will be corroded by the solution for removing the photoresist during the subsequent removal of the photoresist, thus resulting in an uneven surface of the mirror layer, and leading to the decrease of the reflection effect of the mirror layer, which impacts the reliability of the device.

### SUMMARY OF THE INVENTION

Accordingly, the present invention is directed to a process of a micro-display capable of preventing damage of a mirror layer and oxidation of a periphery circuit.

The present invention provides a process of a micro-display. First, a substrate having a pixel region and a periphery circuit region is provided, in which a metal reflection layer is formed in the pixel region, and a periphery circuit is formed in the periphery circuit region. Next, a dielectric layer is formed on the substrate to cover the pixel region and the periphery circuit region. Then, a patterned mask layer exposing the dielectric layer on the metal reflection layer is formed on the dielectric layer. Then, a portion of the exposed dielectric layer is removed by using the patterned mask layer as a mask. Next, the patterned mask layer is removed. And then, a portion of the dielectric layer is removed to expose the metal reflection layer.

According to the process of a micro-display of an embodiment of the present invention, a material of the metal reflection layer is, for example, aluminum, gold, or silver.

According to the process of a micro-display of an embodiment of the present invention, a method for removing a portion of the exposed dielectric layer is, for example, dry etching.

According to the process of a micro-display of an embodiment of the present invention, a method for removing a portion of the dielectric layer to expose the metal reflection layer is, for example, to perform blanket etching until the metal reflection layer is exposed.

According to the process of a micro-display of an embodiment of the present invention, a material of the patterned mask layer is, for example, a photoresist.

In the present invention, a portion of the dielectric layer on the metal reflection layer is first removed through a lithography process and an etching process, and a portion of the dielectric layer remains on the metal reflection layer, thus preventing the damage of the metal reflection layer caused by the contact with a solution for removing the photoresist during the removal of the photoresist, and preventing the oxidation of the periphery circuit resulting from being exposed during the blanket etching.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are schematic cross-sectional views of a process of a micro-display according to embodiments of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

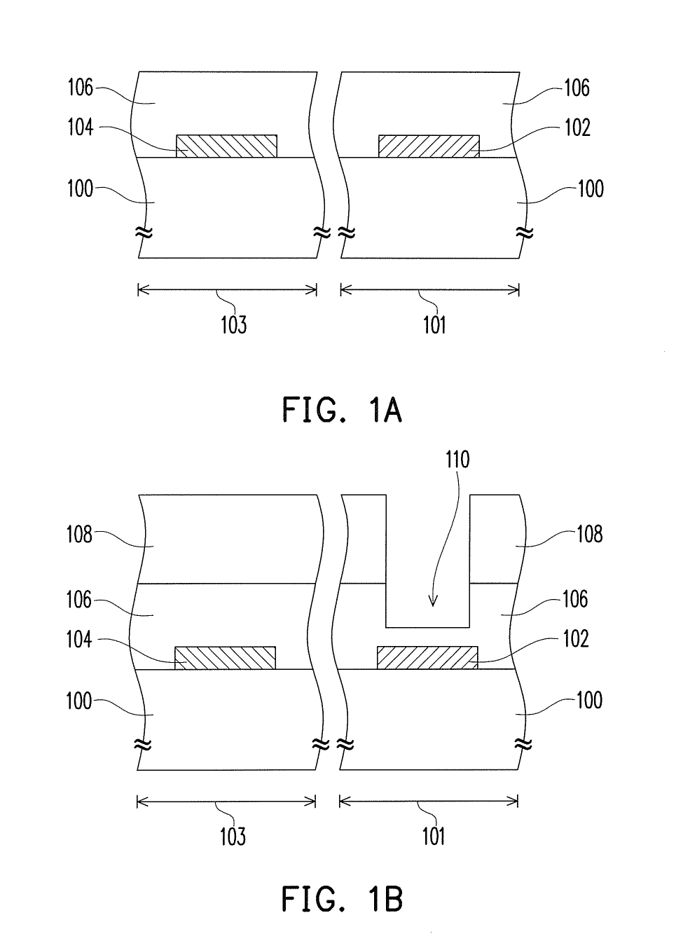

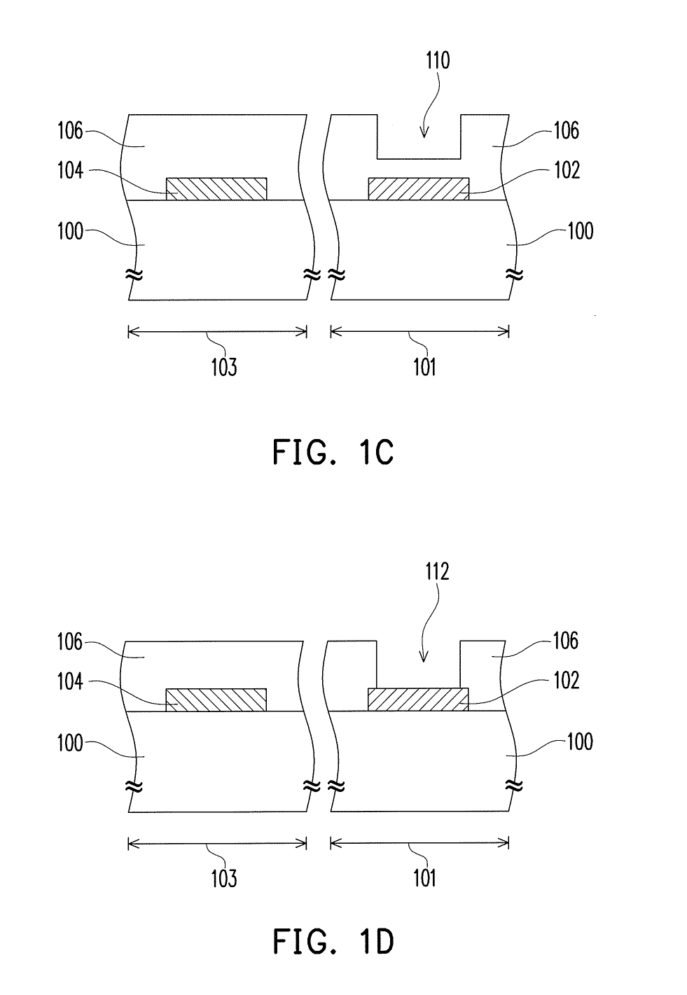

FIGS. 1A to 1D are schematic cross-sectional views of a process of a micro-display according to embodiments of the present invention. First, referring to FIG. 1A, a substrate 100 having a pixel region 101 and a periphery circuit region 103 is provided, in which a metal reflection layer 102 is formed in the pixel region 101, and a periphery circuit 104 is formed in the periphery circuit region 103. The substrate 100 is, for example, a silicon substrate. A material of the metal reflection layer 102 is, for example, aluminum, gold, silver, or other suitable metal reflective material. The metal reflection layer 102 serves as a mirror layer in the micro-display. Therefore, when light is incident in the micro-display, the metal reflection layer 102 can reflect the light. Further, in this embodiment, the periphery circuit region 103 is, for example, on a side of the pixel region 101. In another embodiment, the periphery circuit region 103, for example, surrounds the pixel region 101, that is, the periphery circuit 104 surrounds the metal reflection layer 102.

Next, referring to FIG. 1A again, a dielectric layer 106 is formed on the substrate 100 to cover the pixel region 101 and the periphery circuit region 103. A material of the dielectric layer 106 is, for example, an oxide. A method for forming the dielectric layer 106 is, for example, chemical vapor deposition.

Then, referring to FIG. 1B, a patterned mask layer 108 is formed on the dielectric layer 106. The patterned mask layer 108 exposes the dielectric layer 106 on the metal reflection layer 102, that is, the region to be exposed subsequently of the metal reflection layer 102. A material of the patterned mask layer 108 is, for example, a photoresist. Next, a portion of the exposed dielectric layer 106 is removed by using the patterned mask layer 108 as a mask to form an opening 110 in the dielectric layer 106. A method for removing a portion of the exposed dielectric layer 106 is, for example, dry etching. It should be noted that the depth of the formed opening 110 can be controlled by controlling the etching time of the dielectric layer 106, and the depth of the opening 110 can be adjusted according to actual requirements. In this step, it is important that, after removing a portion of the dielectric layer 106 to form the opening 110, the dielectric layer 106 should still remain on the metal reflection layer 102.

Then, referring to FIG. 1C, the patterned mask layer 108 is removed. As the metal reflection layer 102 still has the dielectric layer 106 remaining thereon, during the removal of the patterned mask layer 108, the damage to the metal reflection layer 102 caused by the corrosion of a solution for removing the patterned mask layer 108 can be prevented, so as to maintain the surface planarization of the metal reflection layer 102.

Thereafter, referring to FIG. 1D, a portion of the dielectric layer 106 is removed to form an opening 112, so as to expose the metal reflection layer 102. A method for removing a portion of the dielectric layer 106 is, for example, performing the blanket etching until the metal reflection layer 102 is exposed. In this step, as the thickness of the dielectric layer 106 in the opening 110 is less than that of the dielectric layer 106 at other positions, after performing the blanket etching and removing the dielectric layer 106 in the opening 110, the dielectric layer 106 on the periphery circuit 104 will not be removed entirely to expose the periphery circuit 104. Further, as the dielectric layer 106 still covers the periphery circuit 104, the oxidation of the periphery circuit 104 can be prevented.

In view of the above, according to the present invention, a portion of the dielectric layer on the metal reflection layer is first removed through a lithography process and an etching process, and then the dielectric layer remaining on the metal reflection layer is removed through blanket etching, thus preventing the periphery circuit from being exposed during the blanket etching, thereby solving the problem of the oxidation of the periphery circuit.

Furthermore, as only a portion of the dielectric layer on the metal reflection layer is first removed through the lithography process and etching process, and a portion of the dielectric layer still remains on the metal reflection layer, during the removal of the photoresist, the metal reflection layer will not contact the solution for removing the photoresist, thus avoiding the corrosion of the metal reflection layer caused by the solution, and maintaining the surface planarization of the metal reflection layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A process of a micro-display, comprising:
providing a substrate having a pixel region and a periphery circuit region, wherein a metal reflection layer is formed in the pixel region, and a periphery circuit is formed in the periphery circuit region;
forming a dielectric layer on the substrate, for covering the pixel region and the periphery circuit region;
forming a patterned mask layer on the dielectric layer, for exposing the dielectric layer on the metal reflection layer;
removing a portion of the exposed dielectric layer by using the patterned mask layer as a mask;
removing the patterned mask layer; and
removing a portion of the dielectric layer in the pixel region and in the periphery circuit region to expose the metal reflection layer.

2. The process of a micro-display according to claim 1, wherein a material of the metal reflection layer comprises aluminum, gold, or silver.

3. The process of a micro-display according to claim 1, wherein a method for removing a portion of the exposed dielectric layer comprises dry etching.

4. The process of a micro-display according to claim 1, wherein a method for removing a portion of the dielectric layer to expose the metal reflection layer comprises performing blanket etching until the metal reflection layer is exposed.

5. The process of a micro-display according to claim 1, wherein a material of the patterned mask layer is a photoresist.
